(19) United States
(12) Patent Application Publication
(10) Pub. No.: US 2025/0324868 A1
(43) Pub. Date: Oct. 16, 2025

(54) DISPLAY PANEL AND DISPLAY DEVICE

(71) Applicant: HKC CORPORATION LIMITED, Shenzhen (CN)

(72) Inventors: YAO LI, Shenzhen (CN); Chuan WU, Shenzhen (CN); Zhonglin CAO, Shenzhen (CN); Tianjun HUANG, Shenzhen (CN); Haljiang YUAN, Shenzhen (CN)

(21) Appl. No.: 18/631,073

(22) Filed: Apr. 10, 2024

(30) Foreign Application Priority Data
Jun. 30, 2023 (CN) 202310803245.7

(51) Int. Cl. H10K 59/131; H10K 59/122; H10K 59/38; H10K 59/80; H10K 102/00; H10K 102/10

(52) U.S. Cl. CPC H10K 59/131; H10K 59/122; H10K 59/38; H10K 59/873; H10K 59/878; H10K 59/8792; H10K 2102/10; H10K 2102/351

(57) ABSTRACT

A display panel and a display device are disclosed. The display panel includes a substrate, multiple light-emitting elements respectively disposed corresponding to multiple opening areas, multiple pixel defining layers respectively disposed corresponding to non-opening areas, an encapsulation layer used to cover the light-emitting elements and pixel defining layers, a color filter layer disposed on the encapsulation layer, and an electrically controlled switching layer disposed on the side of the light-emitting elements adjacent to the substrate. The electrically controlled switching layer includes multiple double-sided flipping balls. Each double-sided flipping ball includes a black light-absorbing layer at a first side, and a reflective layer at a second side. Each double-sided flipping ball has a first state in which the respective light-absorbing layer is disposed to face toward the respective light-emitting element, and a second state in which the respective reflective layer is disposed to face toward the respective light-emitting element.

### CROSS-REFERENCE TO RELATED APPLICATIONS

This application claims the priority and benefit of Chinese patent application number 202310803245.7, entitled “Display Panel and Display Device” and filed Jun. 30, 2023 with China National Intellectual Property Administration, the entire contents of which are incorporated herein by reference.

### TECHNICAL FIELD

This application relates to the field of display technology, and in particular, to a display panel and a display device.

### BACKGROUND

The description provided in this section is intended for the mere purpose of providing background information related to the present application but doesn't necessarily constitute prior art.

With the continuous development of OLED (Organic Light-Emitting Diode) display technology, OLED is increasingly used in displays such as smartphones, tablets, computers, and TVs. OLED displays have the advantages of thin and light, high contrast, fast response, wide viewing angle, high brightness, full color, etc. In order to reduce the reflectivity of external light inside an OLED display, the current mainstream solution is to attach a circular polarizer to the light-emitting surface of the OLED display. However, this solution reduces the light-emitting effect due to the great light loss of the circular polarizer. Another solution is to dispose a color filter on the light-emitting surface of the OLED display to improve the light-emitting efficiency through the color filter. Furthermore, the effect of ambient light reflection in the OLED display can be reduced through the arrangement of a black matrix (BM).

However, when the OLED display panel appears black when the screen is turned off, ambient light, especially relatively strong ambient light, enters the display panel, reaches the anode of the light-emitting element, and is reflected by the anode to form outgoing light, causing the display panel to present problems such as color mixing and glare when in the black state.

### SUMMARY

It is therefore a purpose of this application to provide a display panel and a display device to overcome phenomena such as color mixing and glare caused by ambient light reflection when the display panel is in a black state.

This application discloses a display panel, which includes an opening area and a non-opening area. The display panel further includes a substrate, a light-emitting element, a pixel defining layer, an encapsulation layer, a color filter layer, and an electrically controlled switching layer. A plurality of the light-emitting elements are respectively arranged corresponding to a plurality of the opening areas. Each light-emitting element includes a bottom electrode, a light-emitting layer, and a top electrode that are stacked in sequence in a direction of getting farther away from the substrate. The bottom electrode is a transparent electrode. The pixel defining layer is disposed corresponding to the non-opening area. The encapsulation layer is used to cover the light-emitting element and pixel defining layer. The color filter layer is arranged on the encapsulation layer. The electrically controlled switching layer is disposed on the side of the light-emitting element adjacent to the substrate. There are multiple double-sided flipping balls in the electrically controlled switching layer. A first side of each double-sided flipping ball is provided with a black light-absorbing layer, and a second side of the double-sided flipping ball is provided with a reflective layer. In a first state of the plurality of double-sided flipping balls, the black light-absorbing layer is disposed toward the light-emitting element. In a second state, the reflective layer is disposed toward the light-emitting element.

In some embodiments, the electrically controlled switching layer further includes a plurality of first electrodes and a plurality of second electrodes. The plurality of first electrodes are arranged on a side of the respective double-sided flipping ball adjacent to the respective light-emitting element. The plurality of second electrodes are each disposed on a side of the respective double-sided flipping ball facing away from the respective light-emitting element. The plurality of first electrodes and the plurality of second electrodes are arranged facing each other one by one. The first and second sides of the double-sided flipping ball have different electrical properties. The first electrode and the second electrode are used to: when the respective light-emitting element emits light, control the double-sided flipping ball corresponding to the light-emitting element to be in the second state; when the light-emitting element does not emit light, control the double-sided flipping ball corresponding to the light-emitting element to be in the first state.

In some embodiments, an orthographic projection of each first electrode on the substrate covers an orthographic projection of the respective light-emitting element on the substrate.

In some embodiments, the electrically controlled switching layer further includes a plurality of third electrodes and a plurality of fourth electrodes. The plurality of third electrodes and the plurality of fourth electrodes are respectively disposed in the non-opening areas and are disposed corresponding to the pixel defining layer. The plurality of third electrodes are alternately arranged with the plurality of first electrodes. The plurality of fourth electrodes are alternately arranged with the plurality of second electrodes. The plurality of third electrodes are electrically connected to each other, and the plurality of fourth electrodes are electrically connected to each other for controlling each double-sided flipping ball corresponding to the respective non-opening area to always be in the first state.

In some embodiments, the electrically controlled switching layer includes a plurality of electrically controlled switching sections, and the plurality of electrically controlled switching sections are arranged in one-to-one correspondence with the plurality of light-emitting elements. Each of the electrically controlled switching sections includes a fifth electrode, a sixth electrode, and a plurality of double-sided flipping balls. The fifth electrode is disposed on a side of the electrically controlled switching section adjacent to the light-emitting element. The sixth electrode is disposed on a side of the electrically controlled switching section facing away from the light-emitting element. The fifth electrode and the sixth electrode are used to: when the light-emitting element emits light, control the double-sided flipping ball in the electrically controlled switching section to be in the second state; when the light-emitting element does not emit light, control the double-sided flipping ball in the electrically controlled switching section to be in the first state.

In some embodiments, the electrically controlled switching section further includes a light-shielding structure. A plurality of the light-shielding structures are arranged between two adjacent electrically controlled switching sections, and the light-shielding structures are used to absorb light.

In some embodiments, the thickness of the electrically controlled switching layer is less than or equal to 5 um.

In some embodiments, an isolation layer is disposed between the electrically controlled switching layer and the light-emitting element. The isolation layer is used to isolate the electrically controlled switching layer from the light-emitting element. The display panel further includes a control module. The control module is used to receive the data signal of each of the light-emitting elements, to determine whether the light-emitting element emits light, and to control the state of the electrically controlled switching layer depending on whether the light-emitting element emits light.

In some embodiments, when the display panel is not operating, the electrically controlled switching layer is in the first state. When the display panel is operating, the electrically controlled switching layer is in the second state.

This application also discloses a display device, including a driving circuit and the above-mentioned display panel, where the driving circuit is used to drive the display panel to display.

In this application, the electrically controlled switching layer is used to overcome the phenomenon of the display panel in the black state when ambient light enters the display panel and is reflected to produce color mixing, glare and other phenomena. The electrically controlled switching layer has two states. In the first state, that is, the black light-absorbing layer is arranged corresponding to the light-emitting element. This is applicable to the case when the light-emitting element does not emit light and external ambient light enters the interior of the display panel. Since the anode is also formed of a transparent electrode, after the ambient light passes through the anode, it is absorbed by the black light-absorbing layer and is no longer reflected. In the second state, that is, the reflective layer is disposed corresponding to the light-emitting element. This is applicable when the light-emitting element emits light. After the light-emitting element emits light, because the anode is also in a transparent state, part of the light is emitted from the anode toward the substrate. Through the action of the reflective layer, this part of light is reflected to form outgoing light, thereby enhancing the light utilization efficiency. In this application, by switching the state of the electrically controlled switching layer to adapt to different states of whether the light-emitting element emits light, problems such as color mixing or glare caused by light reflection in the black state of the display panel are improved, the display effect of the display panel is improved, and the display quality is improved.

### BRIEF DESCRIPTION OF DRAWINGS

The accompanying drawings are used to provide a further understanding of the embodiments according to this application, and constitute a part of the specification. They are used to illustrate the embodiments according to this application, and explain the principle of this application in conjunction with the text description. Apparently, the drawings in the following description merely represent some embodiments of the present disclosure, and for those having ordinary skill in the art, other drawings may also be obtained based on these drawings without investing creative efforts. A brief description of the accompanying drawings is provided below.

FIG. 1 discloses a schematic diagram of a first display panel according to a first embodiment of the present application.

FIG. 2 is a schematic diagram of a double-sided flipping ball according to the first embodiment of the present application.

FIG. 3 is a schematic diagram of a second display panel according to the first embodiment of the present application.

FIG. 4 is a schematic diagram of a display panel according to a second embodiment of the present application.

FIG. 5 is a schematic diagram of a display device according to a third embodiment of the present application.

In the drawings: 100. Display panel; 101. Opening area; 102. Non-opening area; 110. Substrate; 120. Light-emitting element; 121. Bottom electrode; 122. Light-emitting layer; 123. Top electrode; 130. Pixel defining layer; 160. Encapsulation layer; 162. First inorganic layer; 163. First organic layer; 164. Second inorganic layer; 170. Color filter layer; 171. Color filter; 180. Electrically controlled switching layer; 181. Double-sided Flipping ball; 181a. Black light-absorbing layer; 181b. Reflective layer; 183. First electrode; 184. Second electrode; 185. Third electrode; 186. Fourth electrode; 187. Fifth electrode; 188. Sixth electrode; 189. Electrically controlled switching section; 190. Light-shielding structure; 191. Isolation layer; 200. Display Device; 210. Driving circuit.

### DETAILED DESCRIPTION OF EMBODIMENTS

It should be understood that the terms used herein, the specific structures and function details disclosed herein are intended for the mere purposes of describing specific embodiments and are representative. However, this application may be implemented in many alternative forms and should not be construed as being limited to the embodiments set forth herein.

As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. In addition, terms “up”, “down”, “left”, “right”, “vertical”, and “horizontal”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure. For those of ordinary skill in the art, the specific meanings of the above terms as used in this application can be understood depending on specific contexts.

Hereinafter this application will be described in further detail with reference to the accompanying drawings and some optional embodiments.

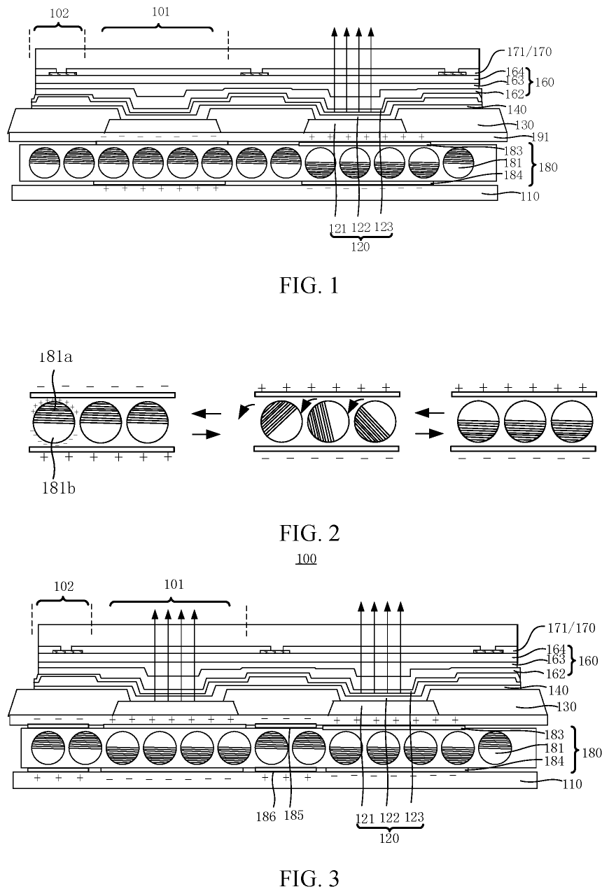

FIG. 1 discloses a schematic diagram of a first display panel ac-cording to a first embodiment of this application. Referring to FIG. 1, this application discloses a display panel 100. The display panel 100 includes an opening area 101 and a non-opening area 102. The opening area 101 may refer to the position of the color filter portion 171, namely the area that can display RGB colors during display, and roughly corresponds to the area between adjacent pixel defining layers 130 of the display panel 100. The non-opening area 102 refers to the position of the black matrix, which is displayed as black during display and roughly corresponds to the area of the pixel defining layer 130. Generally speaking, both the opening area 101 and the non-opening area 102 are located in the display area of the display panel 100.

The display panel 100 further includes a substrate 110, a light emitting unit 120, a pixel defining layer 130, an encapsulation layer 160, a color filter layer 170, and an electrically controlled switching layer 180. A plurality of the light-emitting elements 120 are respectively arranged corresponding to a plurality of the opening areas 101. Along the direction of getting farther away from the substrate 110, the light-emitting element 120 includes a bottom electrode 121, a light-emitting layer 122, and a top electrode 123 that are stacked in sequence. The bottom electrode 121 is a transparent electrode. The pixel defining layer 130 is disposed corresponding to the non-opening area 102. The encapsulation layer 160 is used to cover the light-emitting element 120 and the pixel defining layer 130. The color filter layer 170 is disposed on the encapsulation layer 160. The electrically controlled switching layer 180 is disposed on the side of the light-emitting element 120 adjacent to the substrate 110. A plurality of double-sided flipping balls 181 are disposed in the electrically controlled switching layer 180. The first side of each double-sided flipping ball 181 includes a black light-absorbing layer 181a. The second side of the double-sided flipping ball 181 includes a reflective layer 181b. In a first state of each of the plurality of double-sided flipping balls 181, the black light-absorbing layer 181a is disposed to face toward the respective light-emitting element 120. In a second state, the reflective layer 181b is disposed to face toward the light emitting unit 120.

In this application, the electrically controlled switching layer 180 is used to overcome the phenomenon of the display panel 100 in the black state when ambient light enters the display panel 100 and is reflected to produce color mixing, glare and other phenomena. The electrically controlled switching layer 180 has two states. In the first state, that is, the black light-absorbing layer 181a is arranged corresponding to the light-emitting element 120. This is applicable to the case when the light-emitting element 120 does not emit light and external ambient light enters the interior of the display panel 100. Since the anode is also formed of a transparent electrode, after the ambient light passes through the anode, it is absorbed by the black light-absorbing layer 181a and is no longer reflected. In the second state, that is, the reflective layer 181b is disposed corresponding to the light-emitting element 120. This is applicable when the light-emitting element 120 emits light. After the light-emitting element 120 emits light, because the anode is also in a transparent state, part of the light is emitted from the anode toward the substrate 110. Through the action of the reflective layer 181b, this part of light is reflected to form outgoing light, thereby enhancing the light utilization efficiency. In this application, by switching the state of the electrically controlled switching layer 180 to adapt to different states of whether the light-emitting element 120 emits light, problems such as color mixing or glare caused by light reflection in the black state of the display panel 100 are improved, the display effect of the display panel 100 is improved, and the display quality is improved.

It is worth mentioning that this application utilizes the double-sided flipping ball 181 in the dual-color flipping ball display technology. In particular, it refers to a spherical micro-particle formed by dividing a ball into two halves and painting each half white and black respectively. Then the dual-color ball is coated on a substrate with a silicone resin seat adhesive. Then holes are defined around the particle and filled with a specific liquid. The white side of the particle surface is negative and the black side is positive, so that different charges are present between the two colors to form a dipole, whose direction is controlled by an electric field.

FIG. 2 is a schematic diagram of a double-sided flipping ball ac-cording to the first embodiment of this application. As shown in FIG. 2, based on the above dual-color flipping ball structure, in this embodiment, half of the surface of the spherical particle is coated with a black-color light-absorbing coating to form a black light-absorbing layer 181a, and the other half is coated with a total reflection coating namely a reflective layer 181b. The two sides have different electrical properties. In this application, the total reflection coating has a “−” negative charge and the black light-absorbing layer 181a has a “+” positive charge for explanation.

Still referring to FIGS. 1 and 2, the electrically controlled switching layer 180 further includes a plurality of first electrodes 183 and a plurality of second electrodes 184. The plurality of first electrodes 183 are disposed on a side of the double-sided flipping ball 181 adjacent to the light-emitting element 120. The plurality of second electrodes 184 are disposed on a side of the double-sided flipping ball 181 facing away from the light-emitting element 120. The plurality of first electrodes 183 and the plurality of second electrodes 184 are arranged facing each other one by one. The first and second sides of the double-sided flipping ball 181 have different electrical properties. The first electrode 183 and the second electrode 184 are used to control the double-sided flipping ball 181 corresponding to the light-emitting element 120 to be in the second state when the light-emitting element 120 emits light. The first electrode 183 and the second electrode 184 are further used to control the double-sided flipping ball 181 corresponding to the light-emitting element 120 to be in the first state when the light-emitting element 120 does not emit light.

In this embodiment, voltages of different polarities can be applied to the first electrode 183 and the second electrode 184 respectively to drive the double-sided flipping ball 181 to rotate. When the first electrode 183 is positively charged and the second electrode 184 is negatively charged, the black light-absorbing layer 181a of the double-sided flipping ball 181 is adjacent to the second electrode 184 and the reflective layer 181b is adjacent to the first electrode 183. At this time, this is the second state, in which the reflective layer 181b reflects the light emitted downwardly from the anode layer to form outgoing light. When the first electrode 183 is negatively charged and the second electrode 184 is positively charged, the black light-absorbing layer 181a of the double-sided flipping ball 181 is adjacent to the first electrode 183 and the reflective layer 181b is adjacent to the second electrode 184. At this time, it is the first state, in which the black light-absorbing layer 181a absorbs the light from the external environment that enters the display panel 100 and passes through the anode.

In one embodiment, the thickness of the electrically controlled switching layer 180 is less than or equal to 5 um. Furthermore, the electrically controlled switching layer 180 is arranged as an entire layer, and the double-sided flipping balls 181 are disposed inside the electrically controlled switching layer 180. The double-sided flipping ball 181 may be spherical or ellipsoidal. Relatively speaking, although the outer surface of the double-sided flipping ball 181 is spherical, due to its small size,

The electrically controlled switching layer 180 of this application has a first driving mode, which may be used in two states: a black state when the display panel 100 is completely closed and a use state. When the display panel 100 is not operating, that is, when the display panel 100 is completely closed and the screen is in the black state, the electrically controlled switching layer 180 is controlled to be in the first state, so that the black light-absorbing layers 181a of all the double-sided flipping balls 181 are adjacent to the respective first electrodes 183 so that all the light incident from the outside may be absorbed by the black light-absorbing layer 181a. When the screen is turned off and presents a black state, the electrical properties of the electrodes on both sides are changed so that the black light-absorbing layer 181a faces upward. At this time, the light transmitted through the various film layers and the anode may be completely absorbed by the lower black light-absorbing layer 181a and will no longer reach the outside of the screen, thereby improving the black halo phenomenon of the OLED display panel 100 using the color filter layer 170. When the display panel 100 is operating, that is, when the display panel 100 is in normal use, the electrically controlled switching layer 180 is controlled to be in the second state, so that the reflective layers 181b of all the double-sided flipping balls 181 are brought adjacent to the respective first electrodes 183, so that the light emitted by each light-emitting element 120 to the substrate 110 is reflected by the respective reflective layer 181b as outgoing light and emitted from the light emitting surface of the display panel 100.

Correspondingly, the plurality of first electrodes 183 may be connected to each other, and the plurality of second electrodes 184 may also be connected to each other. Furthermore, in order to achieve requirements such as low power consumption, especially for mobile devices, the first state of the electrically controlled switching layer 180 is the initial state. After being driven by a voltage once, the double-sided flipping ball 181 may remain in the first state without the need for continuous power supply to maintain the electrically controlled switching layer 180 in the first state.

The electrically controlled switching layer 180 of this application has a second driving mode, which may be applied when the display panel 100 partially emits light and partially does not emit light. That is, in this application, each first electrode 183 and each second electrode 184 can be driven independently to achieve different states of the double-sided flipping ball 181 in different sub-pixel areas. Therefore, the electrodes of each sub-pixel area can be controlled individually and independently. For example, if the light-emitting element 120 in a current sub-pixel area emits light, but there are light-emitting elements 120 that do not emit light in the surrounding sub-pixel areas, then the black light-absorbing layer 181a at the position of each non-displayed light-emitting element 120 may face upward, and this sub-pixel will be darker. This can significantly improve the contrast of the screen.

In particular, the display panel 100 further includes a control module, which is used to receive the data signal of each of the light-emitting elements 120 to determine whether the light-emitting element 120 emits light, and to control the state of the electrically controlled switching layer 180 de-pending on whether the light-emitting element 120 emits light. In this solution, data signals may be identified to determine which areas need to be displayed and which areas do not need to be displayed. That is, for the sub-pixel area that needs to emit light, the double-sided flipping ball 181 at the corresponding position is driven to be in the second state. For the sub-pixel area that does not need to emit light, the double-sided flipping ball 181 at the corresponding position is driven to be in the first state, maintaining the black color and reducing reflection of ambient light. In particular, the control module may be disposed in a timing controller or a data Driving circuit.

A modified embodiment under the second driving mode specifically may include dividing the display panel 100 into multiple areas to achieve unified control of the first electrodes 183 and the second electrodes 184 in the multiple areas, thereby controlling the double-sided flipping balls 181 in different areas to be in different states. Thus, adjustment by area is achieved through area-by-area control. Compared with the solution in the previous embodiment, this solution is lower in cost and simpler to implement.

In the case of the second driving mode, this embodiment further provides an additional method for repairing a bright spot of the OLED display panel 100, which includes driving the double-sided flipping ball 181 in the sub-pixel area where the bright spot is located through voltage driving to switch the black light-absorbing layer 181a to always be adjacent to the respective first electrode 183, that is, the electrically controlled switching layer 180 is always maintained in the first state, to achieve repair of the bright spot.

The structure of the electrically controlled switching layer 180 of this application specifically includes two substrates including an upper substrate and a lower substrate. The upper substrate needs to be made of transparent material, such as glass, etc. The lower substrate may share the above-mentioned substrate 110. An isolation layer 191 may be further disposed between the electrically controlled switching layer 180 and the light emitting unit 120. The isolation layer 191 is used to isolate the electrically controlled switching layer 180 from the light-emitting element 120. The isolation layer 191 may be the same as the encapsulation layer 160, where the encapsulation layer includes a first inorganic layer 162, a first organic layer 163, and a second inorganic layer 164 that are sequentially stacked upward from the substrate. The corresponding isolation layer 191 may be an alternately stacked arrangement of inorganic layers and organic layers. Alternatively, a new lower substrate may be provided, and the above-mentioned substrate 110 is disposed on the upper substrate. The electrically controlled switching layer 180 of this application requires two substrates namely the upper and lower substrates to encapsulate the double-sided flipping balls 181.

In particular, the orthographic projection of each first electrode 183 on the substrate 110 covers the orthographic projection of the respective light-emitting element 120 on the substrate 110. The first electrode 183 is disposed in the opening area 101 and is disposed corresponding to the respective light-emitting element 120.

The area of the first electrode 183 is greater than or equal to the effective light-emitting area of the light-emitting element 120. In this solution, the area of the first electrode 183 may be set slightly larger than the effective light-emitting area of the respective light-emitting element 120. Furthermore, the distance between two adjacent first electrodes 183 may be relatively small. There will be some spacing at the opening between the anodes corresponding to the sub-pixels. If there is no electric field in this spacing to control the rotation of the double-sided flipping balls 181, the middle position may be displayed in confusion. Therefore, the electrode edges on both sides of the corresponding lower side of every two adjacent sub-pixels may be at the middle position of the distance between the two anodes, and the electrodes of the two sub-pixels may be separated by a certain distance.

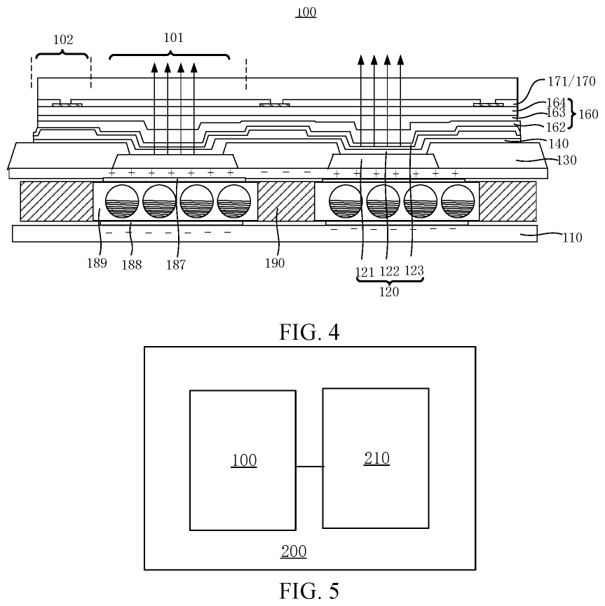

FIG. 3 is a schematic diagram of a second display panel according to the first embodiment of this application. In particular, based on FIG. 1, a third electrode 185 and a fourth electrode 186 are further added. In particular, the electrically controlled switching layer 180 further includes a plurality of third electrodes 185 and a plurality of fourth electrodes 186. The plurality of third electrodes 185 and the plurality of fourth electrodes 186 are each disposed in the non-opening area 102 and are disposed corresponding to the pixel defining layer 130. The plurality of third electrodes 185 are alternately arranged with the plurality of first electrodes 183. The plurality of fourth electrodes 186 are alternately arranged with the plurality of second electrodes 184. The plurality of third electrodes 185 are electrically connected to each other, and the plurality of fourth electrodes 186 are electrically connected to each other for controlling the double-sided flipping ball 181 corresponding to each non-opening area 102 to always be in the first state.

Adjacent light-emitting elements 120 are separated by a pixel defining layer 130, but the pixel defining layer 130 has a certain width. Therefore, the double-sided flipping ball 181 under the pixel defining layer 130 needs to be fixed in the first state with the black light-absorbing layer 181a facing the pixel defining layer 130. Therefore, in this application, a third electrode 185 is further disposed between the first electrodes 183, and a fourth electrode 186 is disposed between the second electrodes 184. It can be understood that the solution of this application can be applied to the three driving methods mentioned above.

FIG. 4 is a schematic diagram of a display panel according to a second embodiment of this application. Referring to FIG. 4, in this embodiment, the electrically controlled switching layer 180 includes a plurality of electrically controlled switching sections 189, and the plurality of electrically controlled switching sections 189 are arranged in one-to-one correspondence with the plurality of light-emitting elements 120. Each of the electrically controlled switching sections 189 includes a fifth electrode 187, a sixth electrode 188, and a plurality of double-sided flipping balls 181. The fifth electrode 187 is disposed on a side of the electrically controlled switching section 189 adjacent to the respective light-emitting element 120. The sixth electrode 187 is disposed on a side of the electrically controlled switching section 189 facing away from the respective light-emitting element 120. The fifth electrode 187 and the sixth electrode 188 are respectively disposed on both sides of the double-sided flipping ball 181 and are used to control the double-sided flipping ball 181 in the electrically controlled switching section 189 to be in the second state when the light-emitting element 120 emits light. When the light-emitting element 120 does not emit light, the fifth electrode 187 and the sixth electrode 188 are used to control the double-sided flipping ball 181 in the electrically controlled switching section 189 to be in the first state.

The difference between this embodiment and the previous embodiment is that this embodiment forms multiple electrically controlled switching sections 189, and each electrically controlled switching section 189 may be independently encapsulated and controlled individually or by means of partitions. When the screen is turned off and appears in a black state, the upper and lower electrodes of each of the double-sided flipping balls 181 under all sub-pixels in the entire screen display area are applied with negative/positive potentials respectively to ensure that the black light-absorbing coatings of all flipping balls face upward. At this time, the natural light is converted into monochromatic light through the color filter portions 171 of each color in the color filter layer 170 of the display panel 100, and then reaches the electrically controlled switching layer 180 through the light-emitting layer 122 and the anode. Since the upper substrate of the double-sided flipping ball 181 is transparent and the upper electrode is a transparent electrode, all light will pass through the transparent electrode and reach the black light-absorbing layer 181a on the double-sided flipping ball 181. Due to the relatively strong light absorption capacity of the black light-absorbing layer 181a, most of the monochromatic natural light that arrives will be completely absorbed by the black light-absorbing layer 181a. At this time, no light will emit out of the screen in the opposite direction, so no obvious halo phenomenon will be seen in the black state, thereby effectively improving the black state reflection shortcoming of the OLED display panel 100.

In particular, the electrically controlled switching section 189 further includes a light shielding structure 190. A plurality of the light-shielding structures 190 are disposed between two adjacent electrically controlled switching sections 189, and the light-shielding structures 190 are used to absorb light.

The light-emitting element 120 in this application may include a red light-emitting element 120, a green light-emitting element 120 and a blue light-emitting element 120, or a white light-emitting element 120. The Color filter 171 may include a red filter part, a green filter part, and a blue filter part, which are disposed corresponding to the red light-emitting element 120, the green light-emitting element 120, and the blue light-emitting element 120, respectively. The light-emitting element 120 includes a top electrode 123, a light-emitting layer 122, and a bottom electrode 121. The bottom electrode 121 is disposed on the substrate 110. The light-emitting layer 122 is disposed on the bottom electrode 121. The top electrode 123 is disposed on the light emitting layer 122.

The bottom electrode 121 may be a metal electrode used as the anode of the light emitting unit 120. The top electrode 123 may use a transparent conductive layer as the cathode of the light-emitting element 120. Driven by a certain voltage, electrons and holes respectively move from the cathode and anode to the light-emitting layer 122 and recombine to emit visible light. However, when the light-emitting element 120 does not emit light, external ambient light may enter the panel. Because the ambient light may include the entire visible light band or a wide spectrum band, the Color filter 171 may filter out most of the wavelength bands of the ambient light. After natural light (white light) passes through the Color filter 171, only the light of the corresponding color is transmitted, and the light in other wavelength bands will be absorbed by the Color filter 171. For example, the red filter may only transmit red light. After the red light enters the light-emitting element 120, since the metal electrode has a relatively high reflectivity, the red light is reflected and emitted from the red filter part or from other pixel positions, causing glare. In this application, by changing the anode to a transparent electrode, the external ambient light will no longer be reflected by the anode to cause problems such as glare or color shift after being emitted into the display panel 100.

FIG. 5 is a schematic diagram of a display device according to a third embodiment of this application. Referring to FIG. 5, this application discloses a display device. The display device 200 includes a driving circuit 210 and the display panel 100 described in any of the above embodiments, where the driving circuit 210 is used to drive the display panel 100 to display.

In this application, the electrically controlled switching layer 180 is used to overcome the phenomenon of the display panel 100 in the black state when ambient light enters the display panel 100 and is reflected to produce color mixing, glare and other phenomena. This application includes but is not limited to the above three driving methods. The electrically controlled switching layer 180 has two states. In the first state, that is, the black light-absorbing layer 181a is arranged corresponding to the light-emitting element 120. This is applicable to the case when the light-emitting element 120 does not emit light and external ambient light enters the interior of the display panel 100. Since the anode is also formed of a transparent electrode, after the ambient light passes through the anode, it is absorbed by the black light-absorbing layer 181a and is no longer reflected. In the second state, that is, the reflective layer 181b is disposed corresponding to the light-emitting element 120. This is applicable when the light-emitting element 120 emits light. After the light-emitting element 120 emits light, because the anode is also in a transparent state, part of the light is emitted from the anode toward the substrate 110. Through the action of the reflective layer 181b, this part of light is reflected to form outgoing light, thereby enhancing the light utilization efficiency. In this application, by switching the state of the electrically controlled switching layer 180 to adapt to different states of whether the light-emitting element 120 emits light, problems such as color mixing or glare caused by light reflection in the black state of the display panel 100 are improved, the display effect of the display panel 100 is improved, and the display quality is improved.

It should be noted that the inventive concept of this application can be formed into many embodiments, but the length of the application document is limited and so these embodiments cannot be enumerated one by one. The technical features can be arbitrarily combined to form a new embodiment, and the original technical effect may be enhanced after the various embodiments or technical features are combined.

The foregoing description is merely a further detailed description of this application made with reference to some specific illustrative embodiments, and the specific implementations of this application will not be construed to be limited to these illustrative embodiments. For those having ordinary skill in the technical field to which this application pertains, numerous simple deductions or substitutions may be made without departing from the concept of this application, which shall all be regarded as falling in the scope of protection of this application.

What is claimed is:

1. A display panel, comprising a plurality of opening areas and a plurality of non-opening areas, and further comprising:
a substrate;
a plurality of light-emitting elements, arranged corresponding to the plurality of opening areas, respectively; wherein each light-emitting element comprises a bottom electrode, a light-emitting layer, and a top electrode that are stacked in sequence in a direction of getting farther away from the substrate, wherein the bottom electrode is a transparent electrode;
a plurality of pixel defining layers, arranged corresponding to the plurality of non-opening areas, respectively;
an encapsulation layer, arranged to cover the plurality of light-emitting elements and the plurality of pixel defining layers;
a color filter layer, arranged on the encapsulation layer; and
an electrically controlled switching layer, arranged on a side of the plurality of light-emitting elements adjacent to the substrate;
wherein the electrically controlled switching layer comprises a plurality of double-sided flipping balls; each of the plurality of double-sided flipping balls has a first side comprising a black light-absorbing layer, and a second side comprising a reflective layer; wherein each of the plurality of double-sided flipping balls has a first state in which the respective black light-absorbing layer is disposed to face toward the corresponding light-emitting element, and a second state in which the respective reflective layer is disposed to face toward the corresponding light-emitting element.

2. The display panel as recited in claim 1, wherein the electrically controlled switching layer further comprises a plurality of first electrodes and a plurality of second electrodes, wherein the plurality of first electrodes are each disposed on a side of the plurality of double-sided flipping balls adjacent to the respective light-emitting element, and the plurality of second electrodes are each disposed on a side of the plurality of double-sided flipping balls facing away from the respective light-emitting element, wherein the plurality of first electrodes and the plurality of second electrodes are disposed facing each other in one-to-one correspondence;
wherein the first side and the second side of each double-sided flipping ball have different electrical properties;
wherein each first electrode and the respective second electrode are used to control the double-sided flipping balls corresponding to the respective light-emitting element to be in the second state in response to the respective light-emitting element emitting light, and control the double-sided flipping balls corresponding to the respective light-emitting element to be in the first state in response to the respective light-emitting element does not emit light.

3. The display panel as recited in claim 2, wherein an orthographic projection of each first electrode on the substrate covers an orthographic projection of the respective light-emitting element on the substrate.

4. The display panel as recited in claim 2, wherein the electrically controlled switching layer further comprises a plurality of third electrodes and a plurality of fourth electrodes, wherein the plurality of third electrodes and the plurality of fourth electrodes are disposed in the plurality of non-opening areas and corresponding to the plurality of pixel defining layers;
wherein the plurality of third electrodes are alternately arranged with the plurality of first electrodes, and wherein the plurality of fourth electrodes are alternately arranged with the plurality of second electrodes;
wherein the plurality of third electrodes are electrically connected to each other and the plurality of fourth electrodes are electrically connected to each other for controlling the double-sided flipping balls corresponding to each non-opening area to always be in the first state.

5. The display panel as recited in claim 1, wherein the electrically controlled switching layer comprises a plurality of electrically controlled switching sections, which are disposed in one-to-one correspondence with the plurality of light-emitting elements;
wherein each of the electrically controlled switching sections comprises a fifth electrode, a sixth electrode, and a plurality of double-sided flipping balls; wherein the fifth electrode is disposed on a side of the respective electrically controlled switching section adjacent to the respective light-emitting element, the sixth electrode is disposed on a side of the respective electrically controlled switching section facing away from the respective light-emitting element; wherein the fifth electrode and the sixth electrode are used to control the double-sided flipping balls in the respective electrically controlled switching section to be in the second state in response to the respective light-emitting element emitting light, and to control the double-sided flipping balls in the respective electrically controlled switching section to be in the first state in response to the respective light-emitting element not emitting light.

6. The display panel as recited in claim 5, wherein each electrically controlled switching section further comprises a light-shielding structure that is disposed between every two adjacent electrically controlled switching sections, and wherein the light-shielding structure is used to absorb light.

7. The display panel as recited in claim 1, wherein the electrically controlled switching layer has a thickness less than or equal to 5 um.

8. The display panel as recited in claim 1, wherein there is further disposed an isolation layer between the electrically controlled switching layer and the plurality of light-emitting elements, and wherein the isolation layer is used to isolate the electrically controlled switching layer from the plurality of light-emitting elements.

9. The display panel as recited in claim 1, wherein further comprising a control module configured to receive a data signal from each of the plurality light-emitting elements, determine whether the light-emitting element emits light, and control a state of the respective electrically controlled switching layer depending on whether the light-emitting element emits light.

10. The display panel as recited in claim 1, wherein when the display panel is not operating, the electrically controlled switching layer is in the first state, and wherein when the display panel is operating, the electrically controlled switching layer is in the second state.

11. The display panel as recited in claim 2, wherein the plurality of first electrodes are electrically connected to each other, and wherein the plurality of second electrodes are electrically connected to each other.

12. The display panel as recited in claim 3, wherein an area of each first electrode is greater than or equal to an effective light-emitting area of the respective light-emitting element.

13. A display device, comprising a driving circuit and a display panel, the driving circuit being used to drive the display panel to display; wherein the display panel comprises a plurality of opening areas and a plurality of non-opening areas, wherein the display panel further comprises:
a substrate;
a plurality of light-emitting elements, arranged corresponding to the plurality of opening areas, respectively; wherein each light-emitting element comprises a bottom electrode, a light-emitting layer, and a top electrode that are stacked in sequence in a direction of getting farther away from the substrate, wherein the bottom electrode is a transparent electrode;
a plurality of pixel defining layers, arranged corresponding to the respective non-opening area, respectively;
an encapsulation layer, arranged to cover the plurality of light-emitting elements and the plurality of pixel defining layers;
a color filter layer, arranged on the encapsulation layer; and
an electrically controlled switching layer, arranged on a side of the plurality of light-emitting elements adjacent to the substrate;
wherein the electrically controlled switching layer comprises a plurality of double-sided flipping balls; each of the plurality of double-sided flipping balls has a first side comprising a black light-absorbing layer, and a second side comprising a reflective layer; wherein each of the plurality of double-sided flipping balls has a first state in which the respective black light-absorbing layer is disposed to face toward the corresponding light-emitting element, and in a second state in which the respective reflective layer is disposed to face toward the corresponding light-emitting element.

14. The display device as recited in claim 13, wherein the electrically controlled switching layer further comprises a plurality of first electrodes and a plurality of second electrodes, wherein the plurality of first electrodes are each disposed on a side of the plurality of double-sided flipping balls adjacent to the respective light-emitting element, and the plurality of second electrodes are each disposed on a side of the plurality of double-sided flipping balls facing away from the respective light-emitting element, wherein the plurality of first electrodes and the plurality of second electrodes are disposed facing each other in one-to-one correspondence;
wherein the first side and the second side of each double-sided flipping ball have different electrical properties;
wherein each first electrode and the respective second electrode are used to control the double-sided flipping balls corresponding to the respective light-emitting element to be in the second state in response to the light-emitting element emitting light, and control the double-sided flipping balls corresponding to the respective light-emitting element to be in the first state in response to the respective light-emitting element does not emit light.

15. The display device as recited in claim 14, wherein an orthographic projection of each first electrode on the substrate covers an orthographic projection of the respective light-emitting element on the substrate.

16. The display device as recited in claim 14, wherein the electrically controlled switching layer further comprises a plurality of third electrodes and a plurality of fourth electrodes, wherein the plurality of third electrodes and the plurality of fourth electrodes are disposed in the plurality of non-opening areas and corresponding to the plurality of pixel defining layers;
wherein the plurality of third electrodes are alternately arranged with the plurality of first electrodes, and wherein the plurality of fourth electrodes are alternately arranged with the plurality of second electrodes;
wherein the plurality of third electrodes are electrically connected to each other and the plurality of fourth electrodes are electrically connected to each other for controlling the double-sided flipping balls corresponding to each non-opening area to always be in the first state.

17. The display device as recited in claim 13, wherein the electrically controlled switching layer comprises a plurality of electrically controlled switching sections, which are disposed in one-to-one correspondence with the plurality of light-emitting elements;
wherein each of the electrically controlled switching sections comprises a fifth electrode, a sixth electrode, and a plurality of double-sided flipping balls; wherein the fifth electrode is disposed on a side of the respective electrically controlled switching section adjacent to the respective light-emitting element, the sixth electrode is disposed on a side of the respective electrically controlled switching section facing away from the respective light-emitting element; wherein the fifth electrode and the sixth electrode are used to control the double-sided flipping balls in the respective electrically controlled switching section to be in the second state in response to the respective light-emitting element emitting light, and to control the double-sided flipping balls in the respective electrically controlled switching section to be in the first state in response to the respective light-emitting element not emitting light.

18. The display device as recited in claim 17, wherein the electrically controlled switching section further comprises a light-shielding structure that is disposed between every two adjacent electrically controlled switching sections, and wherein the light-shielding structure is used to absorb light.
